(19) United States
(12) Patent Application Publication
(10) Pub. No.: US 2026/0313277 A1
(43) Pub. Date: Oct. 8, 2026

(54) Speaker System

(71) Applicant: Blair Potwin, West Hollywood, CA (US)

(72) Inventor: Blair Potwin, West Hollywood, CA (US)

(21) Appl. No.: 19/098,712

(22) Filed: Apr. 2, 2025

(51) Int. Cl. H04R 1/02; H03F 3/183; H04R 3/00

(52) U.S. Cl. CPC H04R 1/025; H03F 3/183; H04R 3/00; H03F 2200/03; H04R 2201/028

(57) ABSTRACT

A speaker system is provided for application within a lidded, polypropylene container. The system comprises an audio receiver, an audio amplifier, and at least one sound exciter, positioned according to the disclosure for producing omni-directional amplified sound emitted through a container lid to the outside surroundings. The audio receiver and audio amplifier may be maintained within the container, while the sound exciter may be securely mounted to an inside surface of the container lid. The device may be configured to receive power from a conventional battery pack.

### GOVERNMENT CONTRACT

Not applicable.

### CROSS-REFERENCE TO RELATED APPLICATIONS

Not applicable.

### STATEMENT RE. FEDERALLY SPONSORED RESEARCH/DEVELOPMENT

Not applicable.

### COPYRIGHT & TRADEMARK NOTICES

A portion of the disclosure of this patent document may contain material which is subject to copyright protection. This patent document may show and/or describe matter which is or may become trade dress of the owner. The copyright and trade dress owner has no objection to the facsimile reproduction by any one of the patent document or the patent disclosure, as it appears in the Patent and Trademark Office patent files or records, but otherwise reserves all copyrights and trade dress rights whatsoever.

### TECHNICAL FIELD

The disclosed subject matter relates generally to audio speakers, and more particularly to audio speakers capable of emitting high-fidelity omni-directional amplified sounds through a lid of a container.

### BACKGROUND

Portable speakers have become increasingly popular as consumers seek convenient ways to enjoy high-quality audio in a variety of environments, from outdoor gatherings and work, to personal travel and beyond.

Conventional portable speakers often prioritize sound output and wireless features, such as Bluetooth connectivity but lack practical features that would make them easier to use, carry, or integrate into everyday activities. Some have attempted to incorporate added functionality, such as integrating the speaker into a bag, bottle, or other device or décor and thus, various speaker integrations have been proposed. For instance, a speaker system including a power amplifier with an exciter and an audio exciter smaller than the exciter that emits sound through the thin metal wall of a refrigerator is disclosed in Chinese Patent CN210441523U.

As another example, a sound exciter and audio amplifier play stereo sounds through the top surface of a narrow depth, wooden meditation platform in US Patent Application US20170290436A1.

As yet another example, a picture frame sound box has a power amplifier and an audio amplifier configured to emit sound through a changeable picture on the front of the sound box in Chinese patent CN218217567U.

Another proposed integration concerns a loudspeaker having an audio amplifier connected to an audio transducer which are attached to a panel by releasable means such as a clip in British patent GB2376829A. The releasable clip can alternatively be adhesives or suction cups.

Likewise, a ceiling speaker has an audio exciter mounted to a sound board with the sound board suspended from a structure in US patent application US 20190075381 A1. The exciter is connected by wire to an audio amplifier.

In addition, in an effort to reduce its visual appearance, a speaker has an exciter connected to a transparent sound panel for emitting sound through the transparent panel in US patent application US200552564A1. A stiff panel is located between the exciter and the transparent sound panel to minimize the bending of the sound panel.

Unfortunately, these proposed integrations often compromise audio performance by limiting speaker placement, obstructing sound paths, or introducing unwanted vibrations, ultimately diminishing the listening experience. Some also have the traditionally larger components of a speaker frame, cone, and speaker enclosure. They do not provide omni-directional sound. That is, conventional speaker designs components project sound in a forward-facing direction. These components are optimized for directional audio performance, particularly at mid and high frequencies, where sound naturally becomes more focused. As a result, conventional speaker configurations limit the listening experience to a specific orientation relative to the speaker.

Thus, although various proposals have been made to solve the problems noted above, none of those in existence combine the characteristics of the present invention. Therefore, there remains a need for multifunctional devices that combine portable audio capability with everyday utility, particularly for audiophiles who desire both convenience and high-fidelity sound.

### SUMMARY

The present disclosure is directed to a speaker system configured to emit omni-directional, amplified sound through a lid of a container such as a toolbox, travel case, beverage cooler, and the like, to an area outside of the container.

For purposes of summarizing, certain aspects, advantages, and novel features have been described. It is to be understood that not all such advantages may be achieved in accordance with any one particular embodiment. Thus, the disclosed subject matter may be embodied or carried out in a manner that achieves or optimizes one advantage or group of advantages without achieving all advantages as may be taught or suggested.

In accordance with one embodiment, the speaker system comprises an audio receiver, an audio amplifier, at least one sound exciter, disposed within a container in relation to a container lid. The container may be generally rectangular in shape with a container lid and define a hollow internal cavity. The cavity may be configured to hold items unrelated to the transmission of sound, such as power tools, or function as a cooler. Of course, stored items will not limit the invention. One of ordinary skill in the art will recognize that the container may carry any number of useful or desirable items without departing from the invention.

The audio receiver may be disposed within the container adjacent to the audio amplifier. Likewise, the audio amplifier may be disposed adjacent to the audio receiver and the at least one sound exciters. The at least one sound exciters may be disposed adjacent to the audio amplifier and may be further securely attached or mounted to an inside surface of the container lid. However, un some embodiments, the audio receiver and the audio amplifier can be configured as a single unit. For instance, the audio receiver may be mounted on an amplifier printed circuit board (PCB). In such cases, the audio receiver may be powered via circuitry on the amplifiers printed circuit board and does not require separate means for receiving power. The integrated amplifier-receiver unit may be disposed within the container, with the at least one sound exciter positioned adjacent to the unit and securely mounted to an inner surface of the container lid.

That is, the sound exciter(s) securely attached to the inner surface of the lid turns the container into a large omni-directional speaker for emitting sound through the container lid to the area outside of the container.

The audio receiver inside the container may be operative to receive audio signals from outside the container, that is, through the container. Audio signals can include, but are not limited to, sounds, voices and music. The audio receiver can be a radio or Bluetooth or any other wireless technology.

In an embodiment, the audio amplifier will receive the audio signal from the audio receiver, amplify the audio signal and transmit the amplified audio signal through wires, in a manner known to those of ordinary skill in the art, to the sound exciter, adjacent to the audio amplifier also inside the container.

The sound exciter(s) are attached or mounted to the inside surface of the container lid using high strength double sided adhesive or glue or other fastener. The particular position of the sound exciter(s) may vary to achieve desired audio characteristics and can be influenced by the size, material properties, and configuration of the container and container lid, with consideration for frequency wavelengths to optimize clarity across mid, bass, and high tones. To that end, it is contemplated that the sound exciter(s) may be placed asymmetrically on the inside of the container lid. In some embodiments, it may be preferred to securely attach the at least on sound exciter on the inside of the container lid according to a ⅖ ⅗ ths methodology in the width and height of the rectangular container lid. For the sake of clarity, a ⅖ ⅗ths methodology will be understood to refer to positioning exciters at points along a surface, like the inside surface of the lid, that are two-fifths and three-fifths of the length or width from a given edge. This placement avoids nodal points in resonant modes, which will improve sound transmission and tonal clarity by exciting the surface of the lid more effectively.

In some embodiments, the sound exciter(s) may be provided for a user to securely attach to the lid according to their own preferences, and the components of the speaker system may be provided as a kit for user assembly or customization.

Thus, the at least one sound exciter is operative to receive the amplified audio signal from the audio amplifier and emit the amplified audio signal through the container lid to the outside surroundings. The at least one sound exciter turns the surface of the container lid into an omni-directional, high-fidelity speaker.

One of ordinary skill in the art will recognize that the system is operative to generate and amplify sound through a container lid while avoiding reliance on the largest components found in conventional speaker systems (e.g. speaker frame, cone and speaker enclosure), which significantly reduces the overall size and weight of the speaker system. As such, storage space is preserved within the container and maintains container functions and utility.

In some embodiments, The container cavity acts as a resonance chamber for the speaker system if the lid is closed. The container cavity acts as a speaker enclosure and greatly improves sound output/quality when closed. Thus, it is contemplated that any walls defining the container may be joined along rounded edges to define rounded corners may improve overall sound quality emitted from the container. That is, a rounded edge (and/or corner) between planar container walls may produce a warmer, richer tone versus a sharp edge or squared-off corner.

Still, the speaker system may be used with the lid open as well. In particular, if the container lid is open, the container acts an individual sound panel without a resonance chamber. In this case, resonance happens solely within the container lid and has reduced output compared to when the lid is closed.

In some embodiments, the container can be formed from foam composites and/or plastics, such as polypropylene, and/or resins such as high performance resin (HPX), polyethylene (PE), and high-density polyethylene (HDPE). These thin lightweight composites have a high compressive strength and moderate to high flexural strength making them excellent impact resistant polymers for containers and ideal surfaces for sound exciters.

Compliant suspension between the sound exciter and the container lid may be provided to further improve the quality of sound emitted through the lid. In some embodiments, the compliant suspension may be enhanced through the use of a soft material such as foam, silicone or rubber. Indeed, in some embodiments, the compliant suspension may be defined by a vapor barrier disposed along an outer edge of the inner surface of the container lid of certain containers such as tool boxes and beverage coolers. As such, soft material may be positioned between the container lid and the container body to enhance the sound quality of the system by reducing noise which might otherwise be caused by the container vibrating.

The system, and in particular, the audio receiver, audio amplifier and the sound exciter, will be configured to receive power from an external or integrated source. In some embodiments, a power source is a rechargeable battery which can be contained within the cavity of the container, as is the speaker system, however, the battery need not be adjacent to the speaker system to practice the invention. In some embodiments, the system may be configured to receive power from a conventional 12 to 20 volt battery.

In an alternative embodiment, the speaker system can have an integrated, replaceable battery.

In some embodiments, the container lid may be hingedly connected to the container along a top edge of the container. However, in some embodiments, the container lid may be freely removed and replaced on the container without departing from the invention.

The speaker system may have one or two or more speakers mounted symmetrically or asymmetrically on the inside lid of the container without limitation and without departing from the invention.

It is contemplated that a speaker system as disclosed and claimed herein may advantageously integrate audio functionality into a practical container, such as a storage case or travel-friendly housing, combining utility and design without sacrificing sound quality.

Thus, it is an object of the invention to provide a speaker system within a container which comprises an audio receiver, an audio amplifier, one or more sound exciters, and container lid for producing omni-directional amplified sound emitted through the container lid to an area outside of the container.

It is another object of the invention to generate high-quality sound on the go while maintaining storage or utility.

One or more of the above-disclosed embodiments, in addition to certain alternatives, are provided in further detail below with reference to the attached figures. The disclosed subject matter is not, however, limited to any particular embodiment disclosed.

### BRIEF DESCRIPTION OF THE DRAWINGS

FIG. 1 shows a perspective view of one embodiment of the speaker system.

FIG. 2 shows an alternative perspective view of the speaker system of FIG. 1 in accordance with one embodiment.

FIG. 3 shows a front cross-sectional view of the speaker system in accordance with one embodiment.

FIG. 4 shows an enlarged cross-sectional view of an exciter, lid, and two-sided tape taken from FIG. 3 in accordance with one embodiment of the speaker system.

FIG. 5 shows an enlarged cross-sectional view of compliant suspension, a lid, and container taken from FIG. 3 in accordance with one embodiment of the speaker system.

FIG. 6 shows an exemplary front cross-sectional view of the speaker system with an exemplary lid in an open position.

FIG. 7 shows an enlarged perspective view of exciters, audio receiver, audio amplifier, means for transferring power, and lid in accordance with one embodiment of the speaker system.

FIGS. 8-9 show alternative exemplary exciter positioning on an inner surface of a lid in accordance with certain embodiments of the speaker system.

The disclosed embodiments may be better understood by referring to the figures in the attached drawings, as provided below. The attached figures are provided as non-limiting examples for providing an enabling description of the method and system claimed. Attention is called to the fact, however, that the appended drawings illustrate only typical embodiments of this invention and are therefore not to be considered as limiting of its scope. One skilled in the art will understand that the invention may be practiced without some of the details included in order to provide a thorough enabling description of such embodiments. Well-known structures and functions have not been shown or described in detail to avoid unnecessarily obscuring the description of the embodiments.

### DETAILED DESCRIPTION

Having summarized various aspects of the present disclosure, reference will now be made in detail to that which is illustrated in the drawings. While the disclosure will be described in connection with these drawings, there is no intent to limit it to the embodiment or embodiments disclosed herein. Rather, the intent is to cover all alternatives, modifications and equivalents included within the spirit and scope of the disclosure as defined by the appended claims.

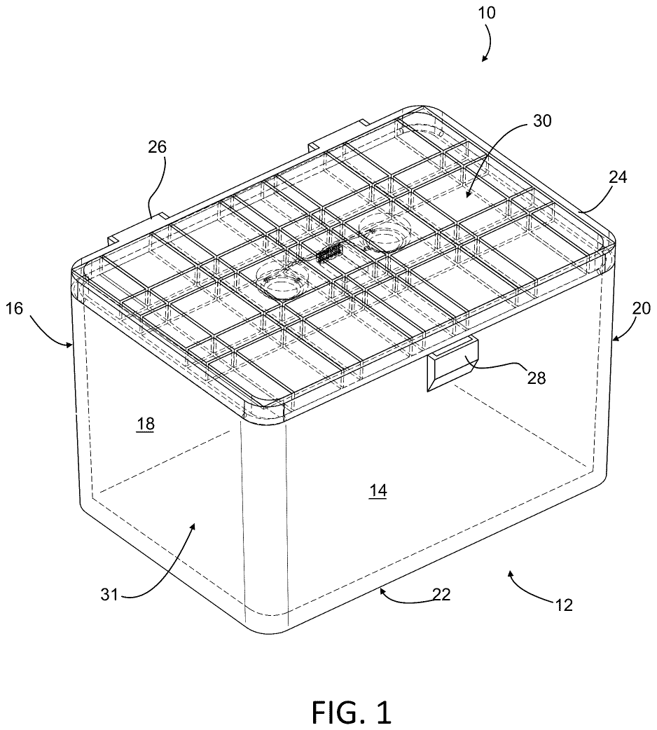

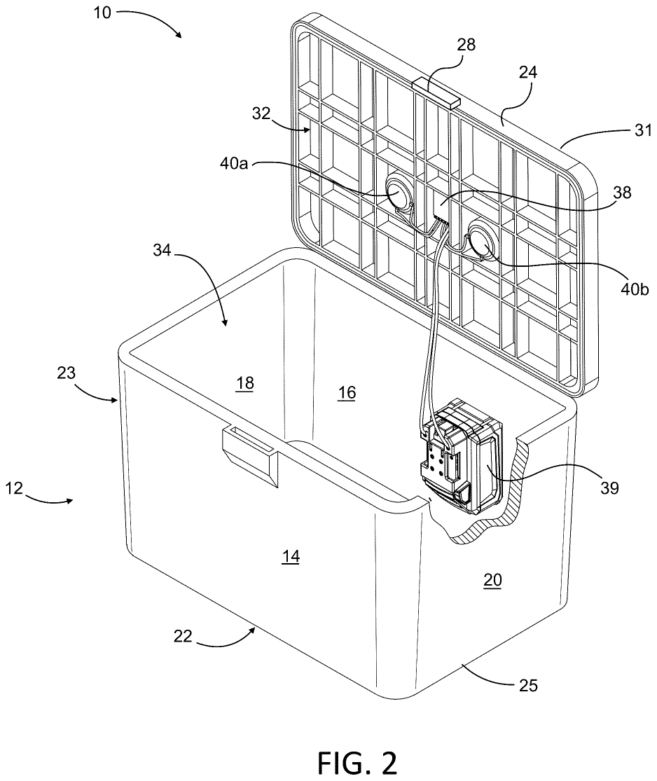

With reference to FIGS. 1 and 2 an embodiment of the speaker system 10 may comprise a container 12 an audio receiver, an audio amplifier, a sound exciter (which will be discussed with reference to later figures), and container lid 24 configured to produce omni-directional amplified sound emitted through the container lid to an area outside of the container. The elements in the figures are not necessarily drawn to scale and are provided for ease of understanding only.

The container 12 may be polygonal, and in the exemplary embodiment, is generally rectangular in shape. In some embodiments, the container is defined by a front sidewall 14 and an opposite and parallel back sidewall 16 as well as a right sidewall 18 and an opposite and parallel left sidewall 20 all extending perpendicularly upward from a bottom wall 22. The front and back sidewalls 14, 16 are perpendicular and sealed to one another along edges 23 to the right and left sidewalls 18, 20. The bottom wall 22 is perpendicular and sealed along the edges 25 to the front and back side walls, and perpendicular and sealed along the edges to the right and left side walls. All of the walls are generally planar in shape.

The container has a lid 24 disposed opposite to the bottom wall perpendicular to the front, back, right, and left side walls 14, 16, 18, 20. The container lid 24 is generally planar in shape.

The container lid 24 may attached to a sidewall, such as the back side wall 16 by a hinge 26 or similar device. The container lid has a latch 28 or similar device for securing the lid 24 to the container 12. The container lid 24 is configured to secure to any of the sidewalls, though it is pictured as securing to the front side wall in the exemplary figures. When the latch 28 is closed, the container lid 24 seals the cavity 34 defined by the container sidewalls 14, 16, 18, 20 and bottom wall 22. However, it is contemplated that the lid may be snug fit to or screwably mateable with the opening defined by the container sidewalls 14, 16, 18, 20. In any event, the container lid 24 can be opened and closed, and elements of the speaker system 10, particularly the sound amplifier, sound receiver, and any exciters, may be positioned on the inside surface of the container lid.

The container 12 defines an outer surface 30 and an inner surface 32. The lid, sidewalls 14, 16, 18, 20 and bottom wall 22 have an outer surface 31 and an inside surface 33 each. The container 12 defines a hollow cavity 34 surrounded by the bottom wall 22, the sidewalls 14, 16, 18, 20 and the lid 24. The cavity can hold items such as power tools or function as a cooler.

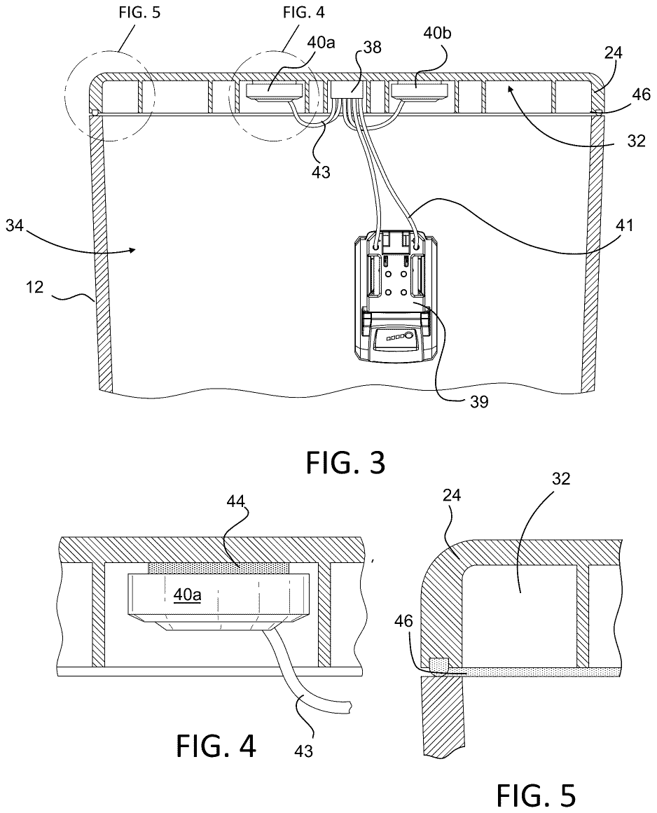

FIG. 3 illustrates components of the speaker system 10 maintained within the container 12. These comprise the audio receiver and the audio amplifier 38 (here integrated in a single PCB), a first and second sound exciter 40a, 40b as applied to the container lid 24. It may be seen that the audio receiver and audio amplifier are integrated in a single unit adjacent to the first and second sound exciters 40a, 40b. The sound exciter is adjacent to the audio amplifier and is attached or mounted to the inside surface 32 of the container lid. The sound exciter(s), here two sound exciters 40a, 40b, securely attached to the lid 24 inner surface 32 turns the container into a omni-directional speaker. Note that in the exemplary figures, the lid 24 features structural lattice work, however, it is contemplated that such lattice work, either by its absence or existence or configuration, will not limit the invention.

The components of the speaker system may all be positioned inside the container 12, with the one or more sound exciter attached to the inside surface 32 of the container lid 24, fully enclosed in the cavity 34 defined by the container sidewalls 14, 16, 18, 20 and bottom wall 22, while sound generated by the speaker system is emitted through the container lid 24 to an area surrounding the outside of the container 12.

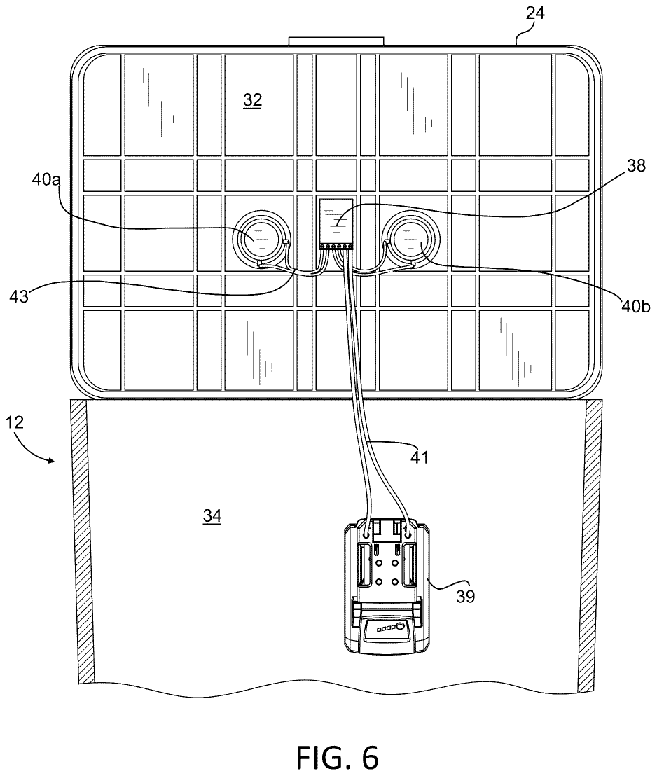

As noted, the audio receiver and audio amplifier may be positioned within the container. In the embodiment shown in FIGS. 3 and 6, audio receiver and audio amplifier are integrated into a single unit such as PCB 38. For example, the audio amplifier may be mounted on the amplifier PCB and in electrical communication with a power source, such as battery 39, configured to provide power to the audio amplifier.

The battery 39 may be held inside the cavity 34 of the container 12, as with other components of the speaker system 10, however the battery 39 need not be adjacent to the speaker system.

As seen in FIG. 3, a rechargeable battery 39 powers the audio receiver and audio amplifier PCB 38 and the sound exciters 40a, 40b of the speaker system 10. In some embodiments, this may be accomplished with an output voltage rating of 12 to 20 volts.

The rechargeable battery is connected to the power inputs on the audio receiver using lengths of silicone shielded copper wire 41 to power the receiver. The rechargeable battery is connected to the power inputs on the audio amplifier using lengths of silicone shielded copper wire 41 to power the audio amplifier. In the exemplary embodiment shown in the figures, the rechargeable battery 39 may be connected to power inputs on the sound amplifier PCB, which is in wired, electrical communication with the sound exciters 40a, 40b and sound receiver.

It is contemplated that utilizing a single battery system for multiple components reduces electronic waste and provides higher performing speaker options at a significantly lower price.

It is contemplated that the rechargeable battery 39 can also be a replaceable rechargeable battery.

In an alternate embodiment, the speaker system can simply have a replaceable battery bodily integrated with, for example, the PCB or other system component.

In some embodiments, the audio receiver is operative receive audio signals from outside the container 12 and through the container 12. Audio signals can include, but are not limited to, sounds, voices and music.

The audio receiver can be a radio or Bluetooth or any other wireless technology fit for such purpose. As such, it is contemplated that the material of the container will be transmissive, without distortion, of the audio signals.

The audio receiver is also operative to transmit the audio signal to the audio amplifier, here integrated with the receiver at PCB 38. The audio amplifier may be operative to receive the audio signal from the audio receiver, amplify the audio signal and transmit the amplified audio signal through wires, such as wires 43 to the sound exciter(s), in close proximity to or otherwise adjacent to the audio amplifier and receiver, inside of the container 12. The wires can be silicone coated copper wires or any other suitable wire known to those of ordinary skill in the art.

In some embodiments, the audio receiver be replaced by an audio player. In such embodiments, there is no audio signal provided externally from the speaker system. The audio player (such as an MP3 player, or a cassette deck or some other analog or digital player) generates an internal (to the container) audio signal to the audio amplifier. In an alternative embodiment, the audio receiver may be an audio source. In such embodiments, the audio source could be both an audio receiver and an audio player.

FIG. 4 shows an enlarged view of one exemplary exciter 40a in accordance with one embodiment of the speaker system. This portion of the disclosure references a single exciter, however, it will be understood that one or more exciters may be utilized without departing from the invention. This has been done in the interest of brevity alone. In particular, it may be seen that the exemplary exciter 40a may is attached or mounted to the inside surface 32 of the container lid 24 using high strength double sided adhesive 44 or glue or other fastener.

The sound exciter(s) are operative to receive the amplified audio signal from the audio amplifier and emits the amplified audio signal through the container lid to the outside surroundings.

A sound exciter creates vibrations with an oscillating mass and transfers energy through a rigid connection to any surface to which it is affixed. The exemplary sound exciter 40a therefore turns the surface of the container lid 24 into an omni-directional, high-fidelity speaker, thus avoiding any need of or reliance on conventional large frame and cone structures of a traditional loud speaker. Sound exciters have a wide frequency response and are capable of producing high fidelity audio with very little distortion, even at high volume.

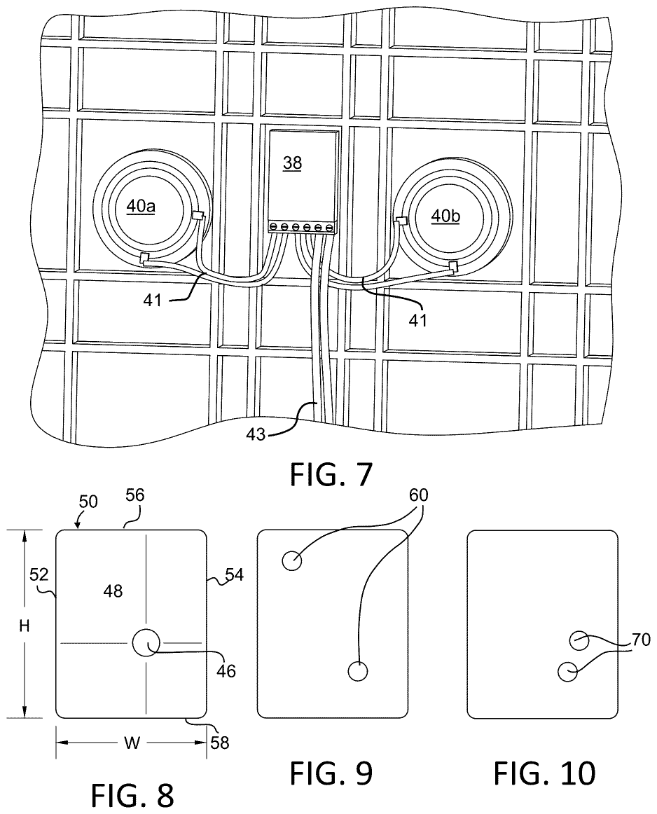

As shown in FIG. 7, silicone shielded copper wires 41 may be attached to terminals on the sound exciter with the opposite ends connecting to the audio amplifier via a lever push-in PCB wire connection block known to those of ordinary skill in the art. Indeed, if provided as a separate component, the audio receiver can be attached to an amplifier PCB by the same means. Alternately, a PCB wire connection block can be used to connect the sound system components.

Stiff wire has been known to interfere with the performance of speaker systems. Therefore, in order to preserve sound quality, the flexible silicone shielded copper wire 41 is preferred for the speaker system. The wavelength of a wireless audio signal to the audio receiver through the container lid 24 is distinguishable, however, and will not interfere with amplified audio signal emitted by the sound exciter(s), also through the container lid 24.

In some embodiments, the amplifier comprises an AM avoidance frequency selection to not accept AM radio frequency interference. If wireless audio signal is Bluetooth, Bluetooth operates at 2400-2483.5 MHz. Thus, a Bluetooth module in accordance with one embodiment of the invention may utilize an industry standard technique known as “frequency hopping” to avoid sound interference in the amplifier.

The sound emitted by the sound exciter(s) is transmitted through the container lid 24 via vibrations, or resonance. The sound producing element in this case is the container lid 24 itself, which takes the place of a cone typically included in a traditional speaker.

Eliminating the largest and most voluminous components found in a traditional speaker system (speaker frame, cone and speaker enclosure) significantly reduces the overall size and weight of the speaker system. The sound exciter(s) instead the container lid surface as a “speaker cone” and do not require an enclosure for sound to resonate within. Instead, the resonance occurs within the surface of the lid 24 itself. In short, the entire sound system does not take up any additional space within the container and does not sacrifice its utility of the container 12 in any way.

Additionally, rounded edges between the planar walls of the container improve overall sound quality of a surface. Indeed, in addition to the foregoing, there are several factors that affect the acoustic output of a material/surface such as composition, size, density, compressive strength and flexural strength.

Thus, the container can be formed from foam composites and/or plastics, such as polypropylene, and/or resins such as high performance resin (HPX), polyethylene (PE), and high-density polyethylene (HDPE). These thin, lightweight composites have a high compressive strength and moderate to high flexural strength making them excellent impact resistant polymers for containers and ideal surfaces for sound exciters.

It is contemplated that materials comprising the container can be injection or blow molded, which are commonly known to those of ordinary skill in the art. Other methods, such as vacuum forming, rotational molding, and thermoforming the materials comprising the container can be used without departing from the invention.

The material of the container should be wavelength transmissive to the wavelengths of the sound being emitted by the speaker system. Thus, the container may be formed from foam composites and/or plastics, such as polypropylene, and/or resins such as HPX, PE, and HDPE, which are all transmissive to the wavelengths of the sound emitted by the speaker system.

The material of the container should not, however, be wavelength absorptive to the wavelengths of the sound being received, amplified, and emitted by the speaker system since, naturally, this wavelength absorption would defeat the omni-directional sound emission functionality of the speaker system. Wavelength absorptive materials include fabric and wood, among others. As such, the material of the container should not be fabric or wood.

Likewise, the material of the container should not be wavelength reflective to the wavelengths of the sound being emitted by the speaker system as such wavelength reflection defeats the omni-directional sound emission functionality of the speaker system. As a point of reference, typical wavelength reflection materials include metal. As such, the material of the container should be non-metallic.

In accordance with an embodiment of the invention, the container cavity 34 acts as a resonance chamber for the speaker system when the lid 24 is closed, that is, positioned at zero degrees relative from the container opening. The container cavity 34 acts as a speaker enclosure in such instances, and greatly improves sound output/quality when closed.

Still, if the container 12 lid 24 is open, that is, positioned in any range from zero degrees to 270 degrees relative to the container opening, the container 12 acts an individual sound panel without a resonance chamber. The resonance happens solely within the container lid 24 and has reduced output, though it still adequately functions for the purposes of this disclosure.

Thus, it is contemplated that the container lid 24 can be freestanding and not attached to the back sidewall or any wall of the container. The container lid 24 may fit snugly along the upper edges of the sidewalls and can therefore be fully removed from the container, not just open and closed by a hinge. As such, any elements of the speaker system mounted on the lid can be fully removed with the container lid. In such cases, components of the speaker system may need to be detached from any wired connection of such components to the battery or other power source.

Compliant suspension 46, shown in FIGS. 3 and 5, allows the container lid 24 to oscillate more freely than without, thereby producing the best possible sound quality and highest output from the sound exciter of the speaker system through the lid 24. A compliantly suspended container lid has excellent acoustic properties due to the great reduction in internally reflected sound energy. A container lid that is allowed to oscillate freely has a greater output, resulting in a higher max volume and wider frequency response. A container lid that is not allowed to oscillate freely will have a much lower maximum volume and significantly reduced bass output.

Compliant suspension 46 may be disposed along the inner surface 32 of the lid 24 and can be enhanced through the use of a soft material such as foam, silicone or rubber, or the vapor barrier found under lids of certain containers such as tool boxes, travel cases and some beverage coolers.

Turning to FIG. 6 it is notable that exemplary sound exciters 40a, 40b are not centered on the container lid 24. Centering a sound exciter on the lid will result in a flatter sound, lacking both low and high frequencies. Instead, a preferred mounting location for sound exciter(s) in the speaker system is determined with a ⅖ ⅗ths methodology. Sound is produced through resonance in the container lid as the sound emanates outward from the location of the sound exciter. The longer the distance from the sound exciter to the edge of the container lid, the lower the tone produced. Inversely, the shorter the distance from the sound exciter to the edge of the container lid, the higher the tone produced.

In an illustrative example of FIG. 8 of positioning a sound exciter 46 of the speaker system on an inner surface 48 of a container lid 50, the width (W) of the rectangular container lid is ⅘ths of the height of the container lid 50. The sound exciter 46 is positioned ⅗ths of the height (H) from the left edge 52 of the container lid 50 and ⅖ths of the height from the right edge 54 of the container lid 50 in the width of the container lid. The sound exciter 46 is positioned ⅗ths of the height from the upper edge 56 of the container lid and ⅖ths of the height from the bottom edge 58 of the container lid in the width of the container lid 50.

In this example, bass notes are produced on the upper section of the container lid 50, treble is produced on the lower and right sections of the container lid and mid-range frequencies are primarily produced on the left side of the container lid 50.

Exemplary alternatives showing asymmetrical placement of exciters 60 and 70 are shown in FIGS. 9 and 10. Thus it will be understood that the exact placement of the exciters can vary and will not limit the invention.

The sound system can utilize a single 2-channel audio amplifier with a single Bluetooth audio receiver capable of transmitting stereo (left/right channel) sound. The amplifier is capable of powering either one or two sound exciters. In the event that the system comprises more than one speaker, a two speaker system, for instance, can have one receiver, one amplifier and two sound exciters. A two speaker system can have two individual speaker systems, each individual speaker system having one receiver, one amplifier and one sound exciter.

In such cases, two speakers can be mounted symmetrically on an inside surface of a container lid. The symmetrical mounting of the two speakers provides a left channel and right channel within a single panel or container lid with common spacing between each speaker and their respective side of the lid for improved sound quality and a more aesthetically pleasing design. Mounting locations can vary depending on user preferences.

In such embodiments, two speakers the speaker system can be mounted asymmetrically on the container lid inside surface. Asymmetrical mounting may allow for multiple panels with one panel used as a left channel and one panel used as a right panel.

The speaker system can have more than two speakers on a panel or container lid. Multiple speakers can be used that will fit on a panel or container lid.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

### CONCLUSIONS, RAMIFICATIONS, AND SCOPE

While certain embodiments of the invention have been illustrated and described, various modifications are contemplated and can be made without departing from the spirit and scope of the invention. For example, the aesthetic appearance, contents held within the container, type and configuration of closures, wheels and other peripheral features will not limit the invention and may vary drastically from use to user. Accordingly, it is intended that the invention not be limited, except as by the appended claim(s).

The teachings disclosed herein may be applied to other systems, and may not necessarily be limited to any described herein. The elements and acts of the various embodiments described above can be combined to provide further embodiments. All of the above patents and applications and other references, including any that may be listed in accompanying filing papers, are incorporated herein by reference. Aspects of the invention can be modified, if necessary, to employ the systems, functions and concepts of the various references described above to provide yet further embodiments of the invention.

Particular terminology used when describing certain features or aspects of the invention should not be taken to imply that the terminology is being refined herein to be restricted to any specific characteristics, features, or aspects of the speaker system with which that terminology is associated. In general, the terms used in the following claims should not be constructed to limit the speaker system to the specific embodiments disclosed in the specification unless the above description section explicitly define such terms. Accordingly, the actual scope encompasses not only the disclosed embodiments, but also all equivalent ways of practicing or implementing the disclosed system, method and apparatus. The above description of embodiments of the speaker system is not intended to be exhaustive or limited to the precise form disclosed above or to a particular field of usage.

While specific embodiments of, and examples for, the method, system, and apparatus are described above for illustrative purposes, various equivalent modifications are possible for which those skilled in the relevant art will recognize.

While certain aspects of the method and system disclosed are presented below in particular claim forms, various aspects of the method, system, and apparatus are contemplated in any number of claim forms. Thus, the inventor reserves the right to add additional claims after filing the application to pursue such additional claim forms for other aspects of the speaker system.

What is claimed is:

1. A speaker system, comprising:
a container defining an inside and an outside;
an audio receiver configured to receive an audio signal from outside of the container as an external audio signal;
an audio amplifier operative to receive the external audio signal from the audio receiver and amplify the external audio signal to generate an amplified audio signal;
at least one sound exciter operative to receive the amplified audio signal from the audio amplifier; and
a container lid having an inner surface and an outer surface;
wherein the at least one sound exciter is securable to the inner surface of the container lid and operative to emit the amplified audio signal through the container lid to an area outside of the container when secured to the inner surface of the container lid.

2. The speaker system of claim 1 wherein the audio receiver is disposed adjacent to the audio amplifier within the container, and the audio amplifier is adjacent to the at least one sound exciter within the container.

3. The speaker system of claim 1 further comprising means for transferring power from an external, rechargeable battery to the audio receiver, the audio amplifier and the at least one sound exciter, wherein the inside of the container is configured to contain the rechargeable battery.

4. The speaker system of claim 1 further comprising a replaceable battery for powering the audio receiver, the audio amplifier and the sound exciter, the replaceable battery being inside the container.

5. The speaker system of claim 1 wherein the container is formed from thin lightweight composites selected from structural foam composites, polypropylene, high performance resin (HPX), polyethylene (PE), and high-density polyethylene (HDPE).

6. The speaker system of claim 1 wherein the container is a toolbox, travel case, or cooler.

7. The speaker system of claim 1 wherein the container is rectangular in shape, said container defined by
front planar sidewall, a back planar sidewall, a left planar sidewall, a right planar sidewall, and a bottom planar wall;
wherein the front and back planar sidewalls are parallel to one another and spaced apart from each other by the right and left planar side walls, which extend perpendicularly therebetween;
wherein the front, back, left, and right planar side walls extend perpendicularly upward from the bottom planar wall to define a hollow cavity as a resonance chamber inside the container; and
wherein the container lid is planar and, when in a closed position over the hollow cavity, is oriented parallel to the bottom planar wall.

8. The speaker system of claim 7, wherein the front, back, right, and left planar sidewalls and bottom planar wall are joined to one another along rounded edges, such that the intersections of two adjoining sidewalls and the bottom wall define rounded corners.

9. The speaker system of claim 1 further comprising
a soft compliant suspension material disposed along an outer edge of the inner surface of the container lid,
wherein the soft compliant suspension material is configured to engage the container body when the lid is closed and operative to enable the lid to freely oscillate in response to audio excitation and dampen unintended mechanical vibrations during operation.

10. The speaker system of claim 1 wherein the one or more sound exciters are secured asymmetrically on the inside of the container lid.

11. The speaker system of claim 10, wherein the container lid has a height and width, the width being ⅘ths of said height, and
wherein a first and a second sound exciter are securely positioned on the inside of the container lid at ⅗ths and ⅖ths of the height and at ⅗ths and ⅖the width, respectively.

12. A speaker system, comprising:
a container defining an inside and an outside;
disposed within the container:
(a) an audio receiver configured to receive an audio signal from an audio player;
(b) an audio amplifier operative to receive the audio signal from the audio player and amplify the audio signal to create an amplified audio signal; and
(c) at least one sound exciter operative to receive the amplified audio signal from the audio amplifier;
a container lid; and
means for supplying power to the audio receiver, the audio amplifier and the at least one sound exciter;
wherein the container is formed of a material selected from the group consisting of polypropylene, high performance resin (HPX), polyethylene (PE), and high-density polyethylene (HDPE);
wherein the at least one sound exciter is securely attached to the inner surface of the container lid, and
wherein the at least one sound exciter is operative to emit the amplified audio signal through said container lid to an area outside of the container.

13. A speaker system within a container comprising:
an audio receiver configured to receive an external audio signal;
an audio amplifier configured to receive the external audio signal from the audio receiver and amplify the external audio signal to generate an amplified audio signal;
a first sound exciter configured to receive the amplified audio signal from the audio amplifier;
a second sound exciter configured to receive the amplified audio signal from the audio amplifier;
a container lid having an inner surface and an outer surface; and
wherein the system is configured to receive power sufficient to operate the audio receiver, the audio amplifier, and the first and second sound exciters from an internal or external power source;
wherein the container defines an inside and an outside and is configured as a resonance chamber,
wherein the first and second sound exciters are securely attached to the inner surface of said container lid, and
wherein the first and second sound exciters are configured to emit the amplified audio signal through the container lid to an area outside of the container.

14. The speaker system of claim 13 further comprising a rechargeable battery operative to supply power to the audio receiver, the audio amplifier, and the first and second sound exciters; wherein the inside of the container is configured to contain the rechargeable battery.

15. The speaker system of claim 13 further comprising a replaceable battery operative to supply power to the audio receiver, the audio amplifier, and the first and second sound exciters; wherein the inside of the container is configured to contain the replaceable battery.

16. The speaker system of claim 13 wherein the container is rectangular in shape, said container defined by
front planar sidewall, a back planar sidewall, a left planar sidewall, a right planar sidewall, and a bottom planar wall;
wherein the front and back planar sidewalls are parallel to one another and spaced apart from each other by the right and left planar side walls, which extend perpendicularly therebetween;
wherein the front, back, left, and right planar side walls extend perpendicularly upward from the bottom planar wall to define a hollow cavity as a resonance chamber inside the container; and
wherein the container lid is planar and, when in a closed position over the hollow cavity, is oriented parallel to the bottom planar wall.
